(19) United States
(12) Patent Application Publication
(10) Pub. No.: US 2019/0378812 A1
(43) Pub. Date: Dec. 12, 2019

(54) DEVICE FOR PRODUCING SEMICO NDUCTOR BUMP METAL LAYER

(71) Applicants: Yu-Hung Huang, Taipei City (TW); Ying Hsien Chen, Taipei City (TW); Hsin Yu Yao, Taipei City (TW); Wei Liang Chan, Taipei City (TW); Kuei Chang Peng, Taipei City (TW); Nai Wei Yu, Taipei City (TW); Yi Hsiang Chen, Taipei City (TW)

(72) Inventors: Yu-Hung Huang, Taipei City (TW); Ying Hsien Chen, Taipei City (TW); Hsin Yu Yao, Taipei City (TW); Wei Liang Chan, Taipei City (TW); Kuei Chang Peng, Taipei City (TW); Nai Wei Yu, Taipei City (TW); Yi Hsiang Chen, Taipei City (TW)

(21) Appl. No.: 16/004,423

(22) Filed: Jun. 10, 2018

(51) Int. Cl. H01L 23/00; H01L 21/67; H01J 37/32; H01J 37/34; C23C 14/02; C23C 14/14; C23C 14/34; C23C 14/56

(52) U.S. Cl. CPC H01L 24/742; H01L 21/67207; H01L 21/67167; H01L 21/67173; H01L 21/6719; H01J 37/32743; H01L 2224/742; H01J 37/3464; C23C 14/021; C23C 14/14; C23C 14/34; C23C 14/566; H01J 37/32899

(57) ABSTRACT

A device for producing semiconductor bump metal layer includes a front end transfer module including a normal pressure transfer chamber, a base material carrier, a heating and carrying interlock vacuum chamber, and a cooling interlock vacuum chamber; a pre-cooking device for receiving the plurality of base materials, forming high vacuum, and baking the base materials; a rear end cleaning sputtering module for receiving the plurality of base materials and cleaning the plurality of base materials and sputtering metal layers; then the plurality of base materials being transferred to the cooling interlock vacuum chamber. The robot in the normal pressure transfer chamber transfers the base materials to the pre-cooking device so as to bake the base materials in high vacuum to remove vapors in the plurality of base materials; then the base materials are transferred to the heating and carrying interlock vacuum chamber for baking again to a predetermined level.

### FIELD OF THE INVENTION

The present invention is related to semiconductor, and in particular to a device for producing semiconductor bump metal layer.

### BACKGROUND OF THE INVENTION

With reference to FIG. 1, a prior art equipment for manufacturing semiconductor bump metal layer is illustrated. The equipment contains a vacuum transfer cavity 10 and an evaporation device 11, a pre-etching reactor chamber 12, a plurality of sputter reactor chambers 13, a first load interlocking vacuum chamber 14, a second load interlocking vacuum chamber 15 which are installed at a periphery of and are communicated to the vacuum transfer cavity 10. A normal pressure transfer chamber 16 is communicated to the first and second load interlocking vacuum chamber 14, 15. A plurality of base material loading devices 17 is aside the normal pressure transfer chamber 16. Each base material loading device 17 is installed with a base material transferring box 18 for locating a plurality of base materials 180 (such as wafers, substrates, etc.)

In the process of manufacturing bump metal layer, a robot (not shown) of the normal pressure transfer chamber 16 will transfer the base material A in the base material transfer box 18 to the first load interlocking vacuum chamber 14. Then an opening between the first loading interlocking vacuum chamber 14 and the normal pressure transfer chamber 16 are closed. Then the first loading interlocking vacuum chamber is vacuumed. When the pressure of the first loading interlocking vacuum chamber achieves to a predetermined high value, a robot 100 in the vacuum transfer cavity 10 transfers the base material 180 in the first load interlocking vacuum chamber 14 to the evaporation device 11, the pre-etching reactor chamber 12 and the plurality of sputter reactor chambers 13 for performing the works of evaporation, de-oxide on aluminum electrodes, and plating a metal layer. Then the base materials are transferred to the second load interlocking vacuum chamber 15 for restoration of pressure. Then they are transferred to the base material loading device 17 by using the robot in the normal pressure transfer chamber 21 so as to complete the manufacturing of semiconductor bumps metal layer.

In the packaging process of semiconductors, it is often to use PI or PBO material as a protection layer of semiconductor chips or as a dielectric layer for wiring. However, it is possible that PI or PBO generates a large amount of water vapors which will oxidize the electrode of joints so as to increase the resistances of the joints. As a result the product will be deserted. Therefore, an evaporation process by using an evaporation device 11 is used before the plating of metal layer for removing vapors in the base material 18 to an acceptable range.

However, since in the equipment, the evaporation device 11 is connected to one output of the vacuum transfer cavity 10 so as to reduce the number of an outputs for using in other object. Therefore, the expansion of the equipment is limited so as to affect the expansions of production and new manufacturing processes.

### SUMMARY OF THE INVENTION

Accordingly, to improve above mentioned defect, the present invention provides a device for producing semiconductor bump metal layer, wherein by the equipments of the present invention, the pre-cooking device to cook the base materials in advance. Then by high temperature, high pressure, and long period baking, the base materials are evaporated completely. Then the base material are transferred to the heating and carrying interlock vacuum chamber for further baking. By the heating module and the temperature detector in the heating and carrying interlock vacuum chamber, the base material are baked precisely to a predetermined level to assure the quality of the proceeding metal layer formed by sputtering. Especially, the pre-cooking device, the heating module and the temperature detector do not occupy any space in the vacuum transfer cavity and thus it will not confine expansion of the element for increment of production and new process.

To achieve above object, the present invention provides a A device for producing semiconductor bump metal layer, comprising: a front end transfer module including a normal pressure transfer chamber, a base material carrier connected to the normal pressure transfer chamber, a heating and carrying interlock vacuum chamber for forming high vacuum and baking the base materials, and a cooling interlock vacuum chamber for cooling the plurality of base materials after the base materials are sputtered with metal layers; the normal pressure transfer chamber being installed with a robot for transferring the plurality of base materials; a pre-cooking device communicated to the normal pressure transfer chamber for receiving the plurality of base materials, forming high vacuum, and baking the base materials; a rear end cleaning sputtering module communicated to the heating and carrying interlock vacuum chamber and the cooling interlock vacuum chamber for receiving the plurality of base materials in the heating and carrying interlock vacuum chamber and cleaning the plurality of base materials and sputtering metal layers; then the plurality of base materials after sputtering being transferred to the cooling interlock vacuum chamber; and wherein the robot in the normal pressure transfer chamber transfers the plurality of base materials in the base material carrier to the pre-cooking device so as to bake the base materials in high vacuum to remove vapors in the plurality of base materials; then the base materials are transferred to the heating and carrying interlock vacuum chamber for baking again to a predetermined level.

### BRIEF DESCRIPTION OF THE DRAWINGS

FIG. 1 is a structural schematic view showing the process of the present invention.

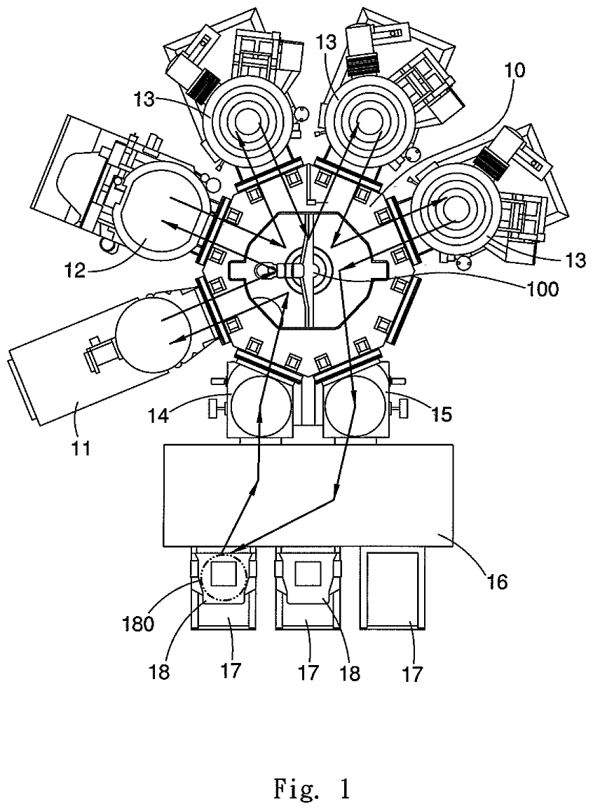

FIG. 2 is a schematic view about the structure of the present invention.

FIG. 3 is a schematic view about the heating devices of the present invention.

FIG. 4 is a schematic view about the operation of the present invention.

FIG. 5 shows another embodiment of the present invention.

### DETAILED DESCRIPTION OF THE INVENTION

In order that those skilled in the art can further understand the present invention, a description will be provided in the following in details. However, these descriptions and the appended drawings are only used to cause those skilled in the art to understand the objects, features, and characteristics of the present invention, but not to be used to confine the scope and spirit of the present invention defined in the appended claims.

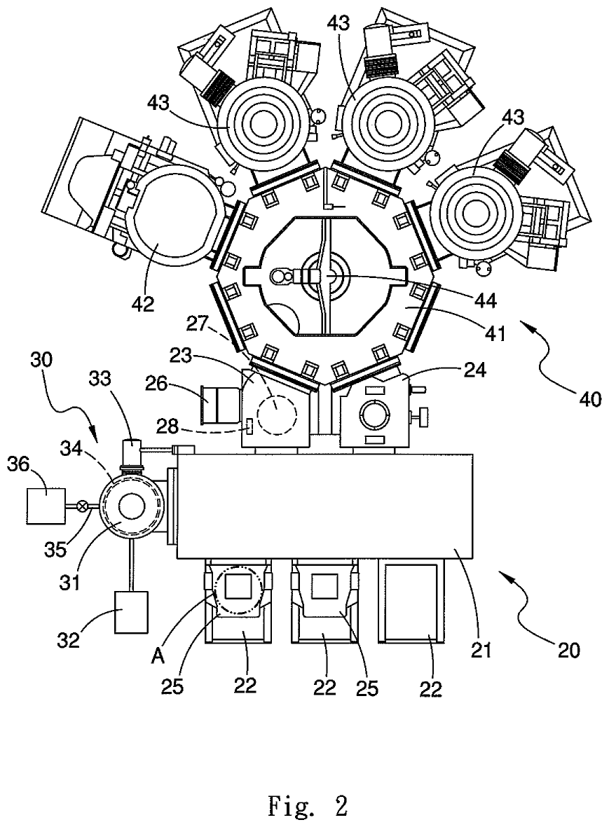

With reference to FIG. 2, the structure of the present invention is illustrated. The present invention includes the following elements.

A front end transfer module 20 includes a normal pressure transfer chamber 21 and a base material carrier 22 connected to the normal pressure transfer chamber 21; a heating and carrying interlock vacuum chamber 23 and a cooling interlock vacuum chamber 24.

The normal pressure transfer chamber 21 is installed with a robot (not shown) for transferring base materials A (such as wafers, substrates, etc.). The base material carrier 22 can be installed with a base material transfer box 25 for placing at least one base material A.

The heating and carrying interlock vacuum chamber 23 serves to receiver the base materials A transferred by the normal pressure transfer chamber 21. One side of the heating and carrying interlock vacuum chamber 23 is installed with a vacuuming device 26 for vacuuming an interior of the heating and carrying interlock vacuum chamber 23. An interior of the heating and carrying interlock vacuum chamber 23 is installed with a heating module 27 and a temperature detector 28 so that the base material A in the heating and carrying interlock vacuum chamber 23 can be baked to a required level in a precise control temperature. The cooling interlock vacuum chamber 24 serves to cool the base materials A after sputter.

The pre-cooking device 30 includes a pre cooking chamber 31, a dry pump 32, and a high vacuum cooling pump 33. The pre-cooking device 30 is communicated to the normal pressure transfer chamber 21 for receiving at least one the base material A. The pre-cooking device 31 includes a heated pure nitrogen input tube 35 for being connected to a heated pure nitrogen input source 36 for providing dried heated pure nitrogen to the pre cooking chamber 31. An interior of the pre cooking chamber 31 is installed with a heating coil 34 for heating the base materials A. The dry pump 32 serves to vacuum the pre cooking chamber 31 to a very low vacuum by using the high vacuum cooling pump 33. By using proper heating temperature and pressure and retaining the status to a predetermined time period, the vapor within the base material A can be evaporated.

The rear end cleaning sputtering module 40 includes a vacuum transfer cavity 41 and a pre-etching reactor chamber 42 and a plurality of sputter reactor chambers 43 which are communicated to the vacuum transfer cavity 41. The vacuum transfer cavity 41 is communicated to the heating and carrying interlock vacuum chamber 23 and the cooling interlock vacuum chamber 24. The vacuum transfer cavity 41 is an interface for transferring an object in vacuum. An interior of the vacuum transfer cavity 41 is installed with a vacuum robot 44 for transferring the base materials A. The pre-etching reactor chamber 42 serves to remove oxide on a surface on a metal electrode on the base materials A so that the metal electrode has a lower contact resistance with other metal plating thereon. The plurality of sputter reactor chambers 43 serve to sputter Ni, Ti, Cu, alloy of Ti and Wu, Au, Al, alloy of Ni and V and other metal layers on the base material A.

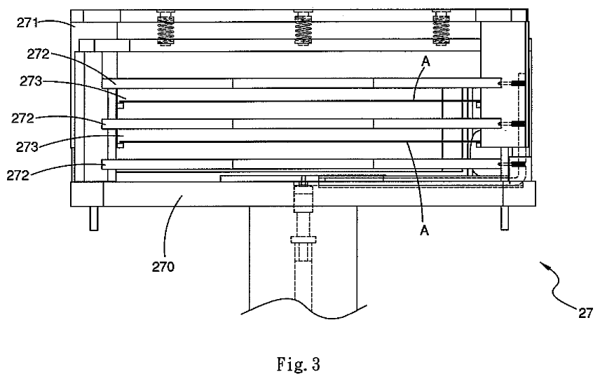

With reference to FIG. 3, the heating module 27 within the heating and carrying interlock vacuum chamber 23 includes a heating frame 270 and a locating frame 271. A plurality of heating plates 272 are parallel installed on the heat frame 270. The locating frame 271 is liftable and descendable on the heating frame 270.

Between the plurality of heating plates 272 are formed with a plurality of locating plates 273 for locating the base material A. When the locating frame 271 moves upwards, the robot in the normal pressure transfer chamber 21 will transfer the base materials A into the locating plates 273, and the robot 44 in the vacuum transfer cavity 41 transfers the plurality of base materials A baked in the plurality of locating frames 273 to the vacuum transfer cavity 41. When the locating frame 271 descends, the plurality of base materials A placed on the respective heating plates 272 are heated. Therefore, by the plurality of heating plates 272 to contact the back sides of the plurality of base materials A, the heating operation is efficient and is uniform.

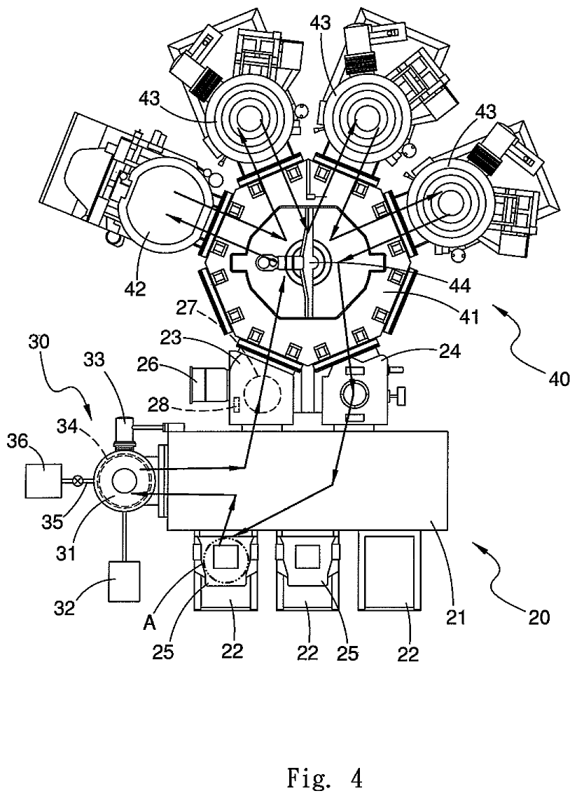

With reference to FIG. 4, the process about the present invention is illustrated.

Step A: An opening between the base material transfer box 25 and the normal pressure transfer chamber 21 is opened by the base material carrier 22.

Step B: the robot in the normal pressure transfer chamber 21 will transfer the plurality of base materials A in the base material transfer box 25 to the pre cooking chamber 31 one by one.

Step C: After a batch of 25 pieces of base materials A are transferred, the opening between the pre cooking chamber 31 and the normal pressure transfer chamber 21 is closed. Then dry heated pure nitrogen is guided to the pre cooking chamber 31 through the heating pure nitrogen input tube 35 and then the heating coil 34 serves to uniformly heat the base materials A in the pre cooking chamber 31.

Step D: Initially, the dry pump 32 serves to vacuum the pre cooking chamber 31 to a pressure of smaller than 100 mtorr. Then the high vacuum cooling pump 33 serves to further vacuum the pre cooking chamber 31 to a very high vacuum and this state is retained to a predetermined time (about 10 minutes). The vapors within the base materials A are completely sucked out by long time baking under high pressure and high vacuum. Therefore, the process of pre baking is complete.

Step E: after the pre baking process is complete, dry heated pure nitrogen is guided into the pre cooking chamber 31 through the heated pure nitrogen input tube 35 so that the pre cooking chamber 31 is returned to normal pressure.

Step F: Then, in the state of inputting the heated pure nitrogen, the opening between the pre cooking chamber 31 and the normal pressure transfer chamber 21 is opened, and the base materials A in the pre cooking chamber 31 is transferred to the heating module 27 in the heating and carrying interlock vacuum chamber 23 by using the robot in the normal pressure transfer chamber 21 (in this embodiment, two base materials A are transferred). Since the above step, the vapor within the base materials A are sucked out completely, in this step, the base materials A still remains preferred dryness in a short time. Furthermore because dry heated pure nitrogen is inputted continuously, so as to retain the pressure from the pre cooking chamber 31 to external space to be a positive pressure. Thus external vapor will not enter into the base materials A.

Step G: The opening between the heating and carrying interlock vacuum chamber 23 and the normal pressure transfer chamber 21 is closed. Then the internal space of the heating and carrying interlock vacuum chamber 23 is vacuumed to a very high level by using the vacuuming device 26 so that the heating module 27 works properly and the base materials A can be baked to a specific level set in the process within the well temperature control by using the temperature detector 28.

Step H: After the process of baking and evaporating in the heating and carrying interlock vacuum chamber 23, the opening between the heating and carrying interlock vacuum chamber 23 and the vacuum transfer cavity 41 is opened and then the base materials A are transferred to the pre-etching reactor chamber 42 for removing the oxide on the surface, and transfers to the sputter reactor chamber 43 for sputtering a layer of Ni, Ti, Cu, alloy of Ti and Wu, Au, Al, alloy of Ni and V and other metals.

Step I After sputtering the metal layer, the base materials A are transferred to the cooling interlock vacuum chamber 24 by the vacuum robot 44 for reduction of temperature and returning to the atmosphere pressure.

STEP J: Then, the opening between the cooling interlock vacuum chamber 24 and the normal pressure transfer chamber 21 are opened, and the robot in the normal pressure transfer chamber 21 serve to transfer the base materials A in the cooling interlock vacuum chamber 24 to the base material transfer box 25 so as to complete the operation of manufacturing the semiconductor bump metal layer.

By the equipments of the present invention, the pre-cooking device 30 to cook the base materials A in advance. Then by high temperature, high pressure, and long period baking, the base materials A are evaporated completely. Then the base material A are transferred to the heating and carrying interlock vacuum chamber 23 for further baking. By the heating module 27 and the temperature detector 28 in the heating and carrying interlock vacuum chamber 23, the base material A are baked precisely to a predetermined level to assure the quality of the proceeding metal layer formed by sputtering. Especially, the pre-cooking device 30, the heating module 27 and the temperature detector 28 do not occupy any space in the vacuum transfer cavity 41 and thus it will not confine expansion of the element for increment of production and new process.

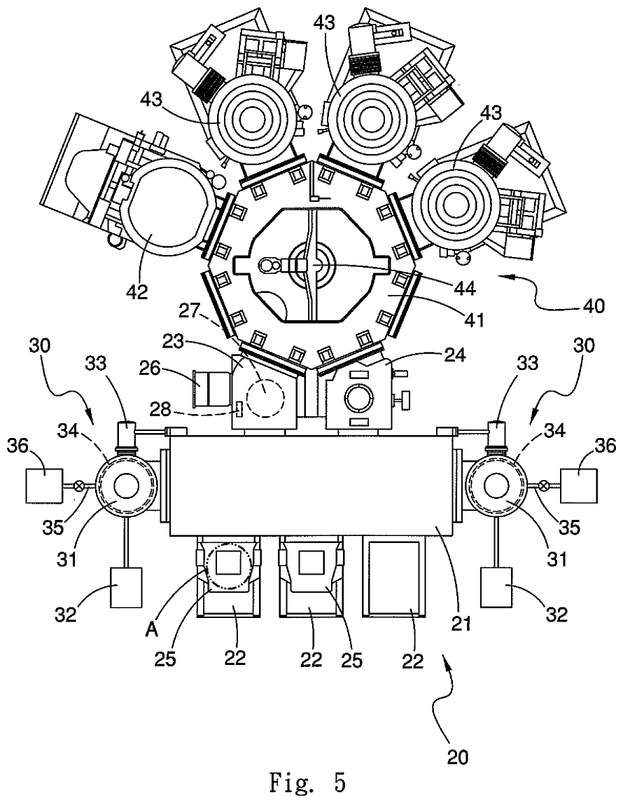

With reference to FIG. 5, another embodiment of the present invention is shown. The structure of this the present invention is almost identical to the former one, however, in this embodiment, a periphery of the normal pressure transfer chamber 21 of the front end transfer module 20 is added with at least one pre-cooking device 30 for increasing the efficiency of evaporation.

The present invention is thus described, it will be obvious that the same may be varied in many ways. Such variations are not to be regarded as a departure from the spirit and scope of the present invention, and all such modifications as would be obvious to one skilled in the art are intended to be included within the scope of the following claims.

What is claimed is:

1. A device for producing semiconductor bump metal layer, comprising:
a front end transfer module including a normal pressure transfer chamber, a base material carrier connected to the normal pressure transfer chamber, a heating and carrying interlock vacuum chamber for forming high vacuum and baking the base materials, and a cooling interlock vacuum chamber for cooling the plurality of base materials after the base materials are sputtered with metal layers; the normal pressure transfer chamber being installed with a robot for transferring the plurality of base materials;
a pre-cooking device communicated to the normal pressure transfer chamber for receiving the plurality of base materials, forming high vacuum, and baking the base materials;
a rear end cleaning sputtering module communicated to the heating and carrying interlock vacuum chamber and the cooling interlock vacuum chamber for receiving the plurality of base materials in the heating and carrying interlock vacuum chamber and cleaning the plurality of base materials and sputtering metal layers; then the plurality of base materials after sputtering being transferred to the cooling interlock vacuum chamber; and
wherein the robot in the normal pressure transfer chamber transfers the plurality of base materials in the base material carrier to the pre-cooking device so as to bake the base materials in high vacuum to remove vapors in the plurality of base materials; then the base materials are transferred to the heating and carrying interlock vacuum chamber for baking again to a predetermined level.

2. The device for producing semiconductor bump metal layer as claimed in claim 1, wherein the base material carrier is installed with a base material transfer box for receiving the base materials.

3. The device for producing semiconductor bump metal layer as claimed in claim 1, wherein one side of the heating and carrying interlock vacuum chamber is installed with a vacuuming device for vacuuming interior thereof; an interior of the heating and carrying interlock vacuum chamber is installed with a heating module and a temperature detector for baking the plurality of base materials under precise control.

4. The device for producing semiconductor bump metal layer as claimed in claim 4, wherein the heating module further includes a heating frame and a locating frame; a plurality of heating plates are parallel installed on the heat frame; the locating frame is liftable and descendable on the heating frame; between the plurality of heating plates are formed with a plurality of locating plates for locating the base materials; when the locating frame moves upwards, the robot in the normal pressure transfer chamber will transfer the base materials into the locating plates, and the robot in the vacuum transfer cavity transfers the plurality of base materials baked in the plurality of locating frames to the vacuum transfer cavity; and when the locating frame descends, the plurality of base materials placed on the respective heating plates are heated; therefore, by the plurality of heating plates to contact the back sides of the plurality of base materials, the heating operation is efficient and is uniform.

5. The device for producing semiconductor bump metal layer as claimed in claim 1, wherein the pre-cooking device includes a pre cooking chamber, a dry pump, and a high vacuum cooling pump; the pre-cooking device is communicated to the normal pressure transfer chamber for receiving at least one the base materials; the pre-cooking device includes a heated pure nitrogen input tube for being connected to a heated pure nitrogen input source for providing dried and heated pure nitrogen to the pre cooking chamber; an interior of the pre cooking chamber is installed with a heating coil for heating the base materials; the dry pump serves to vacuum the pre cooking chamber to a very low vacuum by using the high vacuum cooling pump; by using predetermined heating temperature and pressure and retaining this temperature and pressure to a predetermined time period, vapor within the base materials can be evaporated.

6. The device for producing semiconductor bump metal layer as claimed in claim 1, wherein the rear end cleaning sputtering module includes a vacuum transfer cavity, a pre-etching reactor chamber and a plurality of sputter reactor chambers which are communicated to the vacuum transfer cavity; the vacuum transfer cavity is communicated to the heating and carrying interlock vacuum chamber and the cooling interlock vacuum chamber; the vacuum transfer cavity is an interface for transferring an object in vacuum; and an interior of the vacuum transfer cavity is installed with a vacuum robot for transferring the base materials.

7. The device for producing semiconductor bump metal layer as claimed in claim 6, wherein the pre-etching reactor chamber serves to remove oxide on a surface of a metal electrode on the base materials so that the metal electrode has a lower contact resistance with other metal plating thereon; the plurality of sputter reactor chambers serve to sputter metal layers on the base materials.

8. The device for producing semiconductor bump metal layer as claimed in claim 1, wherein a further pre-cooking device is installed to a periphery of the normal pressure transfer chamber of the front end transfer module.

9. The device for producing semiconductor bump metal layer as claimed in claim 1, wherein a plurality of pre-cooking devices are installed to a periphery of the normal pressure transfer chamber of the front end transfer module at one time.

10. The device for producing semiconductor bump metal layer as claimed in claim 1, wherein the pre-cooking device bakes 25 pieces of base materials at one time and the heating and carrying interlock vacuum chamber supply two pieces of base materials at one time.
